(19) United States
(12) Patent Application Publication
(10) Pub. No.: US 2008/0045018 A1
(43) Pub. Date: Feb. 21, 2008

(54) Method of chemical-mechanical polishing and method of forming isolation layer using the same

(75) Inventors: Il-young Yoon, Hwaseong-si (KR); Jae-ouk Choo, Yongin-si (KR); Ja-eung Koo, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/826,899

(22) Filed: Jul. 19, 2007

(30) Foreign Application Priority Data
Aug. 16, 2006 (KR) 10-2006-0077179

(51) Int. Cl. H01L 21/461

(52) U.S. Cl. 438/693; 257/E21.483

(57) ABSTRACT

A method of chemical-mechanical polishing (CMP) and a method of forming an isolation layer using the same are provided. The method of chemical-mechanical polishing includes performing a first chemical-mechanical polishing operation on an insulating layer having a zeta potential with a first polarity by supplying a first slurry on the insulating layer, wherein the first slurry includes a first abrasive and ionic surfactants having a zeta potential with a second polarity opposite to the first polarity. The method of forming an isolation layer includes forming a mask layer on a substrate, etching the substrate to a desired depth using the mask layer such that a trench is formed in the substrate, forming the insulating layer on the substrate and performing the first chemical-mechanical polishing operation described above.

### PRIORITY STATEMENT

This application claims the benefit of priority under 35 U.S.C. §119 from Korean Patent Application No. 10-2006-0077179, filed on Aug. 16, 2006, in the Korean Intellectual Property Office, the disclosure of which is incorporated herein in its entirety by reference.

### BACKGROUND

1. Field

Example embodiments relate to a method of chemical-mechanical polishing (CMP). Other example embodiments relate to a method of forming an isolation layer using the same.

2. Description of the Related Art

Chemical-mechanical polishing (CMP) may be performed to planarize a surface of a substrate by a combination of a mechanical polishing effect using abrasives and a chemical reaction effect using acidic or basic solution.

CMP may be used to planarize various materials such as polishing a silicon oxide layer for Inter Layer Dielectric (ILD) or Shallow Trench Isolation (STI), forming a tungsten (W) plug and copper interconnecting, forming poly-silicon and a deep trench for fabricating a capacitor, etc.

FIG. 1 is a graph showing zeta potential values of a silicon oxide layer, a silicon nitride layer and ceria particles in accordance with a variation in pH. FIG. 2 is a diagram illustrating a reaction of negative surfactants with a silicon oxide layer and a silicon nitride layer at pH 5-6 in a conventional chemical-mechanical polishing operation.

Referring to FIG. 1, at pH 5-6, a zeta potential of the silicon oxide layer (denoted as “O”) is a negative value, a silicon nitride layer (denoted as “N”) has a zeta potential value of about zero and the ceria particles (denoted as “C”) have a positive zeta potential value.

Referring to FIG. 2, a slurry, which has a pH value 5-6 and includes ceria particles 56 and negative surfactants 58, is provided. If a silicon oxide layer 54 is polished using the slurry at pH 5-6, then more surfactants are disposed (or positioned) on the silicon nitride layer 52 than on the silicon oxide layer 54 due to a static electrical attractive force of the silicon oxide layer 54 and the negative surfactants of an exposed silicon nitride layer 52. The silicon oxide layer 54 is over etched compared to the silicon nitride layer 52. Due to dishing, a corner portion (denoted as “X” in FIG. 6) of the silicon nitride layer 52 contacting the silicon oxide layer 54 is damaged.

FIG. 3 is a diagram illustrating an apparatus for performing a chemical mechanical polishing (CMP) operation.

Referring to FIG. 3, a wafer 20 is transferred to a CMP apparatus 10 by means of a robot 12. In the CMP apparatus 10, a transfer unit 13 transports the wafer 20 to a first plate 14. A chemical mechanical polishing (CMP) operation is performed on the first plate 14 by supplying a slurry including silica particles. The wafer 20 is transferred from the first plate 14 to a second plate 16. On the second plate 16, a slurry including ceria particles and anionic surfactants is supplied (or provided) on the wafer 20 for polishing. The wafer is transferred from the second plate 16 to a third plate 18. On the third plate 18, the slurry including the ceria particles and the anionic surfactants is again supplied to polish the wafer.

FIGS. 4 through 6 are diagrams illustrating sectional views of a conventional method of forming an isolation layer.

The CMP apparatus illustrated in FIG. 3 may be used to perform a CMP operation on the silicon oxide layer 54 on substrate 50, forming an isolation layer. The isolation layer may be formed by performing three CMP operations using the CMP apparatus illustrated in FIG. 3.

Referring to FIG. 4, a silicon nitride layer 52 is formed on a substrate 50. The silicon nitride layer 52 functions as a mask layer. Using the silicon nitride layer 52 as a mask, a portion of the substrate 50 is etched to a depth of about 4,000 Å, forming a trench 60 in the substrate 50. A silicon oxide layer 54 is formed on the substrate 50 and in the trench 60. A first CMP operation is performed on the substrate 50 positioned on a first plate (not shown) using a first slurry including the silica particles.

Referring to FIG. 5, the substrate 50 is transferred (or positioned) on a second plate (not shown). A second CMP operation is performed on the silicon oxide layer 54 deposited (or formed) on the substrate 50, forming a planarized thin silicon oxide layer 54. A second slurry including ceria particles and anionic surfactants is used during the second CMP operation. The second CMP operation is performed faster than the first CMP operation.

Referring to FIG. 6, a third CMP operation is performed on the planarized thin silicon oxide layer 54 using the second slurry having the ceria particles and the anionic surfactants, exposing the silicon nitride layer 52. The third CMP operation may be performed slower than the second CMP operation. The substrate 50 may be positioned (or transferred) on a third plate (not shown) during the third CMP operation.

Referring to FIG. 6, the trench 60 may be substantially wide. In other example embodiments, a pattern (not shown) may be formed in an active region of the substrate 50. If the wide trench 60 (or pattern) is formed at a lower density, then a height h₁ of the trench 60 (or pattern) may be greater than a height h₂ of the silicon oxide layer 54 due to the CMP operations. The height h₁ of the trench 60 is about 4,000 Å. The height h₂ of the silicon oxide layer 54 within the trench 60 is about 3,500 Å. As such, dishing (e.g., about 1,300-1,400 Å) of the silicon oxide layer 54 formed over the trench 60 occurs. The trench 60 is not be completely filled.

Dishing damages the substrate 50 contacting the silicon oxide layer 54, reducing the reliability of a semiconductor device formed on the substrate 50. Dishing occurs because an etch selectivity of the silicon oxide layer 54 is greater than an etch selectivity of the silicon nitride layer 52 due to the static electrical attractive force of the anionic surfactants and the silicon nitride layer 52 and/or a static electrical repulsive force of the anionic surfactants and the silicon oxide layer 54.

FIGS. 7 through 9 are scanning electron microscope (SEM) photographs of an isolation layer formed on a substrate according to conventional methods.

Referring to FIG. 7, if an isolation layer i is formed according to conventional methods, then dishing occurs. As such, a boundary X is formed between mask layer (e.g., a silicon nitride layer 52) on an upper surface of an active region and a isolation layer (e.g., silicon oxide layer 54). The boundary X show in FIG. 7 corresponds to the boundary X formed between the silicon nitride layer 52 on the substrate 50 and the upper portion of the silicon oxide layer 54 within the trench 60 shown in FIG. 6.

Referring to FIGS. 8 and 9, the boundary X may be damaged.

### SUMMARY

Example embodiments relate to a method of chemical-mechanical polishing (CMP). Other example embodiments relate to a method of forming an isolation layer using the same.

Example embodiments provide a method of chemical-mechanical polishing (CMP) capable of reducing (or preventing) dishing of a layer subjected to polishing. Example embodiments also provide a method of forming an isolation layer capable of reducing (or preventing) dishing of the insulating layer for device isolation increasing reliability of a semiconductor device.

According to example embodiments, there is provided a method of chemical-mechanical polishing including forming a substrate including a mask layer and an insulating layer having a zeta potential with a first polarity. The insulating layer is polished using a first slurry including abrasives and ionic surfactants having a second polarity opposite to the first polarity of the insulating layer. The first slurry may be used in a first CMP operation on the insulating layer. The first CMP operation may be one of three CMP operations performed on the insulating layer.

According to other example embodiments, the insulating layer may be polished using a second slurry including the abrasives and the ionic surfactants having the first polarity or neutral surfactants, prior to performing the first chemical-mechanical polishing. The second slurry may be used in a second CMP operation on the insulating layer.

According to yet other example embodiments, the insulating layer may be polished using a third slurry including the abrasives (excluding surfactants) prior to performing the first CMP operation. The third slurry may be used in a third CMP operation on the insulating layer.

The second CMP operation may be performed prior to the first CMP operation. The third CMP operation may be performed prior to the second CMP operation in order that the insulating layer may be planarized in three CMP operations.

The first CMP operation may be more effective if the insulating layer is larger than the mask layer.

According to example embodiments, there is provided a method of forming an isolation layer including forming a mask layer on a substrate and forming a trench in the substrate. The trench may be formed by etching the substrate to a desired depth using the mask layer as a mask. An isolation layer is formed on the substrate with the trench therein. A first CMP operation is performed on the isolation layer using a first slurry including abrasives and ionic surfactants with a polarity opposite to a polarity of the zeta potential of the isolation layer. The mask layer may be removed after performing the first CMP operation, forming the isolation layer.

A second CMP operation may be performed on the isolation layer using a second slurry including abrasives and ionic surfactants with a polarity identical to (or substantially the same) as the zeta potential of the isolation layer or neutral surfactants, prior to performing the first CMP operation.

A third CMP operation may be performed on the isolation layer using a third slurry including abrasives (excluding surfactants) prior to performing the first CMP operation and after forming the isolation layer.

The second CMP operation may be performed prior to the first CMP operation and the third CMP operation.

The isolation layer may be a silicon oxide layer. The mask layer may be a silicon nitride layer.

### BRIEF DESCRIPTION OF THE DRAWINGS

Example embodiments will be more clearly understood from the following detailed description taken in conjunction with the accompanying drawings. FIGS. 1-4 represent non-limiting, example embodiments as described herein.

FIG. 1 is a graph showing the zeta potential values of a silicon oxide layer (O), a silicon nitride layer (N) and ceria particles (C) in accordance with a variation in pH;

FIG. 2 is a diagram illustrating a reaction of negative surfactants with a silicon oxide layer and a silicon nitride layer at pH 5-6 according to conventional chemical-mechanical polishing (CMP);

FIG. 3 is a diagram illustrating an apparatus for chemical-mechanical polishing (CMP);

FIGS. 4 through 6 are diagrams illustrating sectional views of a conventional method for forming an isolation layer;

FIGS. 7 through 9 are scanning electron microscope (SEM) photographs of an isolation layer formed on a substrate according to conventional methods;

FIG. 10 is a graph showing zeta potential values of a silicon oxide layer (O), a silicon nitride layer (N) and ceria particles (C) in accordance with a variation in pH;

FIG. 11 is a diagram illustrating a method of chemical-mechanical polishing at a pH of 5-6 according to example embodiments;

FIG. 12 is a diagram illustrating a method of chemical-mechanical polishing at a pH of 10-11 according to example embodiments;

FIGS. 13 through 15 are diagrams illustrating sectional views of a method of forming an isolation layer according to example embodiments; and

FIG. 16 is a graph showing the results of an evaluation of dishing occurring on the isolation layer formed by a method of forming an isolation layer according to example embodiments.

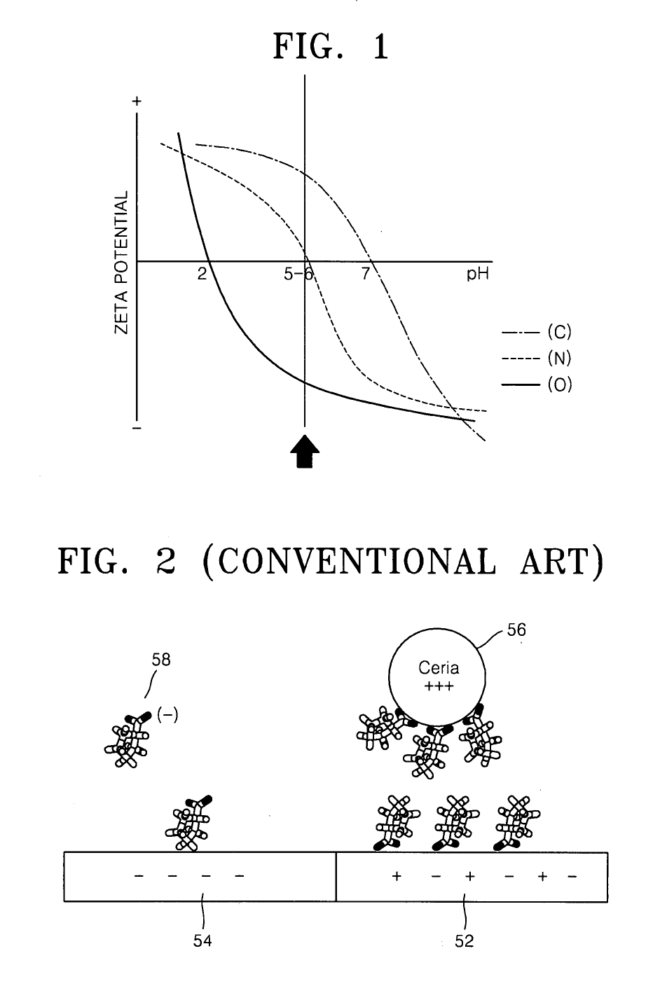

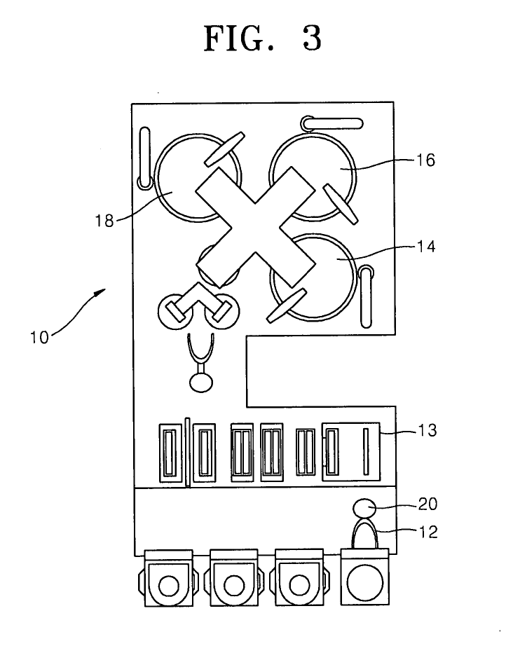

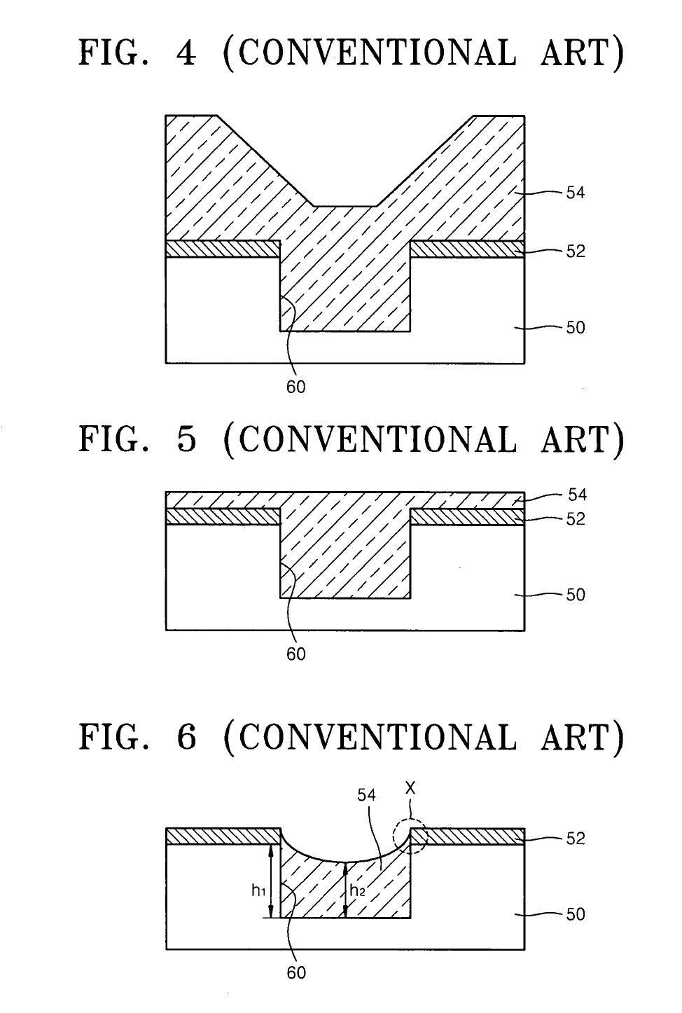

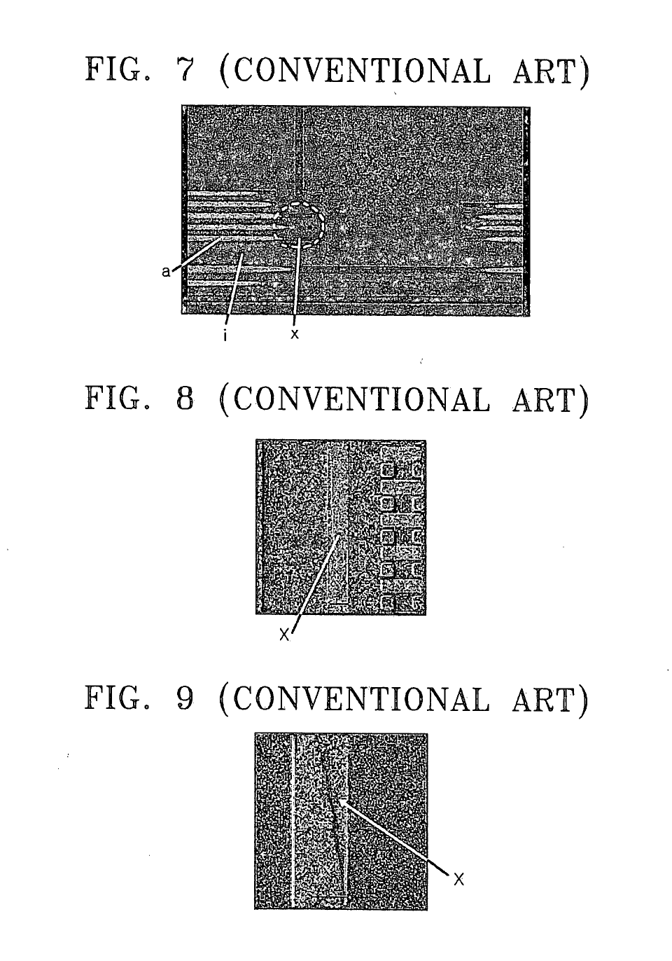

### DETAILED DESCRIPTION

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while the example embodiments are capable of various modifications and alternative forms, embodiments thereof are shown by way of example in the drawings and will herein be described in detail. It should be understood, however, that there is no intent to limit example embodiments to the particular forms disclosed, but on the contrary, the example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, processes, elements and/or components, but do not preclude the presence or addition of one or more other features, integers, steps, operations, processes, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to the example embodiments described.

Example embodiments relate to a method of chemical-mechanical polishing (CMP). Other example embodiments relate to a method of forming an isolation layer using the same.

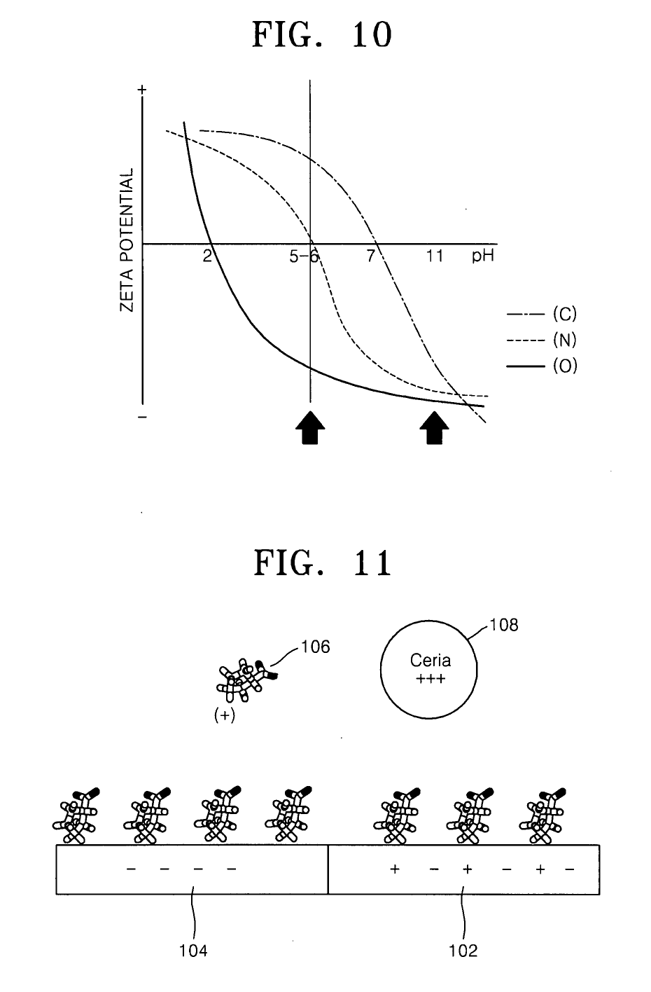

A method of chemical-mechanical polishing (CMP) according to example embodiments will be described with reference to FIGS. 10-12.

According to example embodiments, a silicon nitride layer may be used as a mask layer and a silicon oxide layer may be used as an insulating layer.

FIG. 10 is a graph showing zeta potential values of a silicon oxide layer (O), a silicon nitride layer (N) and ceria particles (C) in accordance with a variation in pH. Returning to FIG. 10, at pH 5-6, a zeta potential value of a silicon oxide layer (O) is negative, a zeta potential value of a silicon nitride layer (N) is zero, and a zeta potential value of ceria particles (C) is positive.

FIG. 11 is a diagram illustrating a method of chemical-mechanical polishing (CMP) at pH 5-6 according to example embodiments.

Referring to FIG. 11, a first slurry is supplied to a substrate (not shown) having an insulating layer 104 and a mask layer 102 formed thereon. The insulating layer 104 may be a silicon oxide layer 104. The mask layer 102 may be a silicon nitride layer 102. The silicon oxide layer 104 may be subjected to chemical-mechanical polishing wherein the silicon nitride layer 102 functions as a mask. The first slurry may be supplied between a polishing pad and the substrate in order to perform a first chemical-mechanical polishing (CMP) operation.

The first slurry may include abrasives 108 and positive ionic surfactants 106. The pH of the first slurry may be 5-6. The positive ionic surfactants 106 may include salts having an amine functional group. The abrasives 108 in the first slurry may be ceria particles (e.g., cerium oxide (CeO₂) particles), silica particles (e.g., silicon oxide (SiO₂) particles), alumina particles (e.g., aluminum oxide (Al₂O₃) particles) or mixtures thereof. The ceria particles may be used as the abrasives 108 due to the selectivity of the ceria particles when polishing the silicon oxide layer 104.

Referring to FIG. 11, if the first slurry having a pH of 5-6 is supplied to the substrate, then the positive ionic surfactants 106 are bonded (or attracted) to the silicon oxide layer 104 having a negative zeta potential value. The positive ionic surfactants 106 may be bonded to the silicon nitride layer 102 having a zeta potential value of about zero (or neutral). The positive ionic surfactants 106 have a greater probability of bonding to the silicon oxide layer 104 due to static electrical attractive forces. Excessive polishing of the silicon oxide layer 104 may be prevented (or reduced) by the ceria particles 108.

According to other example embodiments, the first slurry may include polyethylene glycol-based and polyhydroxyl-based neutral surfactants. The first slurry may include a mixture of positive ionic surfactants 106 and the neutral surfactants. The static electric attractive forces of the first slurry including the neutral surfactants may be weaker than the first slurry including the positive ionic surfactants. Because there is no (or weaker) repulsive forces on the silicon nitride layer 102, the neutral surfactants are more likely to bond to the silicon oxide layer 104. If the first slurry including the neutral surfactants is supplied to the substrate, dishing caused by over-etching of the silicon oxide layer 104 may be reduced compared to the silicon nitride layer 102.

The first CMP operation may be performed more effectively if the insulating layer to be subjected to polishing is larger than the mask layer (e.g., if a pattern density of the mask layer is 15% or less).

The first CMP operation may be the sole chemical-mechanical polishing operation performed. In other example embodiments, the first CMP operation is performed after performing another CMP (hereinafter “second CMP operation”) to planarize a surface of the insulating layer. The first CMP operation may require more time than the second CMP operation.

According to example embodiments, the mask layer 104 (e.g., silicon oxide layer 104) may be formed on the insulating layer (e.g., silicon nitride layer 102). Prior to performing the first CMP operation, a second slurry including the abrasives 108 and anionic surfactants may be supplied (or provided) on the silicon oxide layer 104 using a polishing pad. The abrasives 108 in the second slurry may be the ceria particles having a desired selectivity with respect to the silicon oxide layer 104. The second slurry may be used in the second CMP operation. The anionic surfactants of the second slurry exert a repulsive force against the silicon oxide layer 104 having the negative zeta potential at pH 5-6 such that the second CMP operation may be performed substantially faster than the first CMP operation. The silicon oxide layer 104 may be partially subjected to the second CMP operation. The silicon oxide layer 104 partially planarized by the second CMP operation may be subjected to the first CMP operation, increasing productivity of the semiconductor device and/or preventing (or reducing) dishing to increase reliability.

In yet other example embodiments, the silicon oxide layer 104 is formed on the silicon nitride layer 102. Prior to performing the first CMP operation, a third slurry including the abrasives 108 may be supplied (or provided) on the silicon oxide layer 104 using a polishing pad. The third slurry may include silica particles as the abrasives 108. The third slurry may exclude surfactants to increase a contact probability between the silica particles and the silicon oxide layer 104. The third slurry may be used in a third CMP process. The third CMP operation may require more time to perform than the second CMP operation.

The second CMP operation, the third CMP operation and the first CMP operation may be performed sequentially to planarize the silicon oxide layer 104 in three operations.

The silicon oxide layer 104 subjected to polishing may have a negative zeta potential value at pH 5-6. The second slurry including the anionic surfactants may be supplied when the insulating layer 104 (e.g., the silicon oxide layer 104) subjected to polishing has a positive zeta potential value at a desired pH. The anionic surfactants may be at least one selected from the group consisting of arginnine, lysine, alanine, glycine, picolinic acid, N-dimethylglycine, 3-aminobutyric acid and isonicotinic acid. The second slurry may include the neutral surfactants or a mixture of the anionic surfactants and the neutral surfactants.

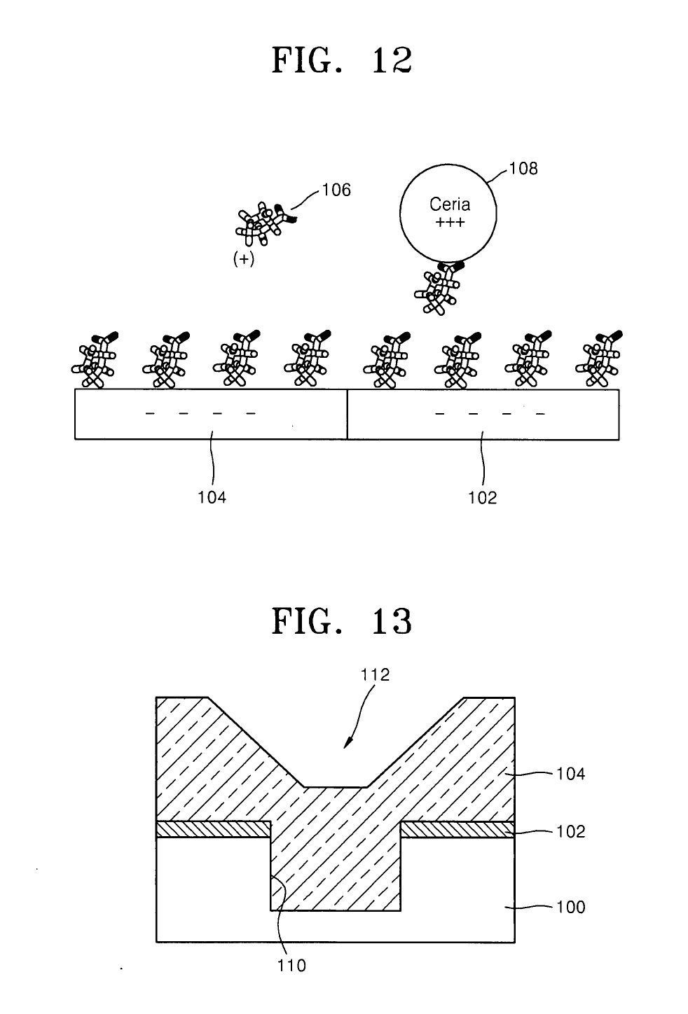

Hereinafter, a chemical-mechanical polishing (CMP) of the silicon oxide layer on the silicon nitride layer at pH 10-11 will be described in detail with reference to FIGS. 10 and 12.

FIG. 12 is a diagram illustrating a method of chemical-mechanical polishing (CMP) at pH 10-11 according to example embodiments.

Referring to FIG. 12, after supplying (or providing) the first slurry to the substrate on which the silicon oxide layer 104 subjected to polishing (i.e., the insulating layer) and the silicon nitride layer 102 (i.e., the mask layer), the substrate is rotated (or positioned) to contact the polishing pad, performing the first CMP operation. The first slurry includes the abrasives 108 (e.g., ceria particles) and the positive ionic surfactants 106.

Referring to FIG. 10, the silicon oxide layer (O), the silicon nitride layer (N) and the ceria particles (C) each have a negative zeta potential value at pH 10-11. If the first slurry is supplied, then the positive ionic surfactants 106 bond to the silicon oxide layer 104 and the silicon nitride layer 102 at substantially the same probability (or rate). The silicon oxide layer 104 may be protected (or masked) by the positive ionic surfactants, preventing (or reducing) over-etching of the silicon oxide layer 104.

Prior to performing the first CMP operation, the silicon oxide layer 104 may be planarized by performing the second CMP operation, the third CMP operation or the second CMP operation followed by the third CMP operation, as described above. By performing the first CMP operation after the second CMP operation or the third CMP operation, over-etching of the silicon oxide layer 104 is prevented (or reduced) by the static electrical attractive forces of the silicon oxide layer 104 and the positive ionic surfactants 106. As such, the silicon nitride layer 102 may function as an etch stop layer.

FIGS. 13 through 15 are diagrams illustrating sectional views of a method of forming an isolation layer according to example embodiments.

Referring to FIG. 13, a silicon nitride layer 102 pattern is formed on a substrate 100. The silicon nitride layer 102 may have a thickness of about 750 Å. Using the silicon nitride layer 102 as a mask layer, the substrate 100 may be etched to have a depth of about 4,000 Å, forming a trench 110. A silicon oxide layer 104 may be formed on the substrate 100 over the silicon nitride layer 102. The silicon oxide layer 104 may be formed in the trench 100.

A third CMP operation may be performed by supplying (or providing) a third slurry (not shown) including abrasives on the substrate 100 having the silicon oxide layer 104 thereon. The abrasives may be silica particles. As illustrated in FIG. 13, the silicon oxide layer 104 may be formed with a varying thickness, forming a groove 112. If the abrasives are ceria particles, then the ceria particles may be trapped in the groove 112.

According to yet other example embodiments, the third CMP operation may be performed with a third slurry including the silica particles. If silica particles are used during the third CMP operation, the groove may not be as deep compared to use of ceria particles during the third CMP operation. The silica particles may not be trapped in the groove 112.

A polishing speed of the third CMP operation is slower if the third slurry includes the silica particles compared to the ceria particles. The ceria particles may be used if an increase in productivity of the semiconductor device is desired.

In other example embodiments, the third CMP operation may not be performed in order to increase productivity of the semiconductor device.

After performing the third CMP operation (so as to avoid trapping the ceria particles), the second slurry including the ceria particles and the anionic surfactants may be used to perform the second CMP operation. As described above, the ceria particles have a relatively larger particle size, demonstrating an increased polishing efficiency. Because the silicon oxide layer 104 subjected to polishing has a negative zeta potential value at pH 2 or greater, the anionic surfactants may not bond to the silicon oxide layer 104 due to the repulsive forces. The silicon oxide layer 104 has an increased probability of contacting the ceria particles due to a pressure applied by the polishing pad. The zeta potential of the ceria particles at pH 2-7 is positive. As such, the probability of contact between the ceria particles and the silicon oxide layer 104 is higher. The productivity of the semiconductor device may be increased by increasing the polishing speed.

A second CMP operation is performed using the second slurry including the anionic surfactants with a polarity identical to (or substantially the same as) the silicon oxide layer 104. The second slurry may include the ceria particles with a polarity opposite to a polarity of the silicon oxide layer 104.

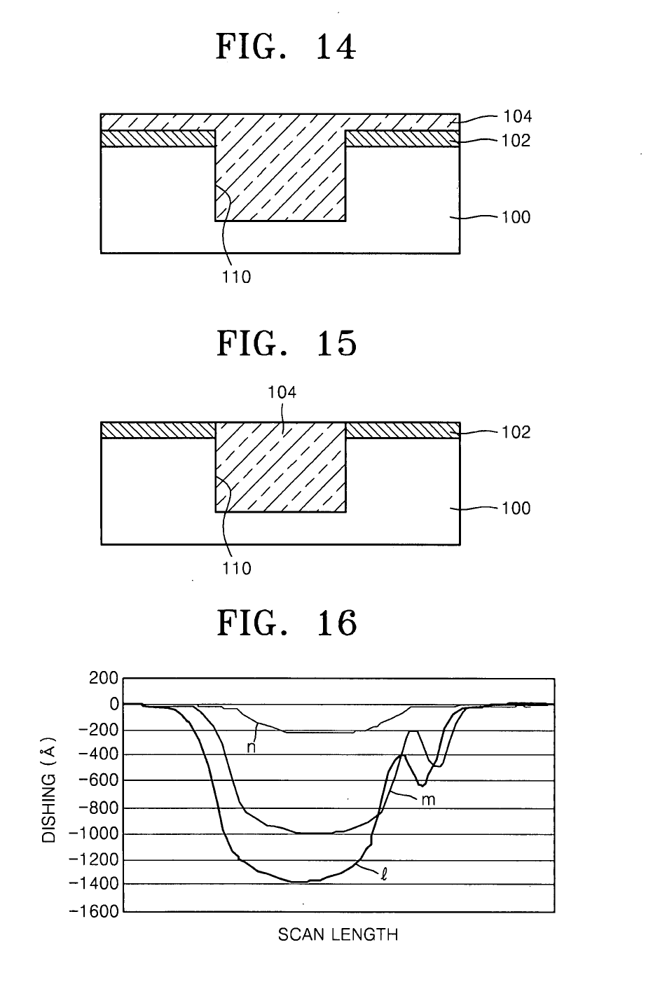

Referring to FIG. 14, the silicon oxide layer 104 may have a more uniform surface after planarization by the second CMP operation. The first slurry, which includes the surfactants and the ceria particles having a polarity opposite to a polarity of the silicon oxide layer 104, is supplied (or provided) on the silicon oxide layer 104 using a polishing pad to perform a first CMP operation. If the pH of the first slurry is 5-6, then the zeta potential of the silicon oxide layer 104 has a negative value. The first slurry may include the positive ionic surfactants. The positive ionic surfactants may bond to the silicon oxide layer 104 to prevent (or reduce) over-etching of the silicon oxide layer 104. Although the silicon oxide layer 104 is polished until the silicon nitride layer 102 is exposed, dishing may be prevented or reduced. Dishing is caused by over-etching of the silicon oxide layer 104 having the positive ionic surfactants bonded thereto compared to the silicon nitride layer 102.

Referring to FIG. 15, the first CMP operation is performed after performing the third CMP operation and the second CMP operation such that the resultant structure is planarized without dishing.

FIG. 16 is a graph showing the results of an evaluation of dishing occurring on the isolation layer formed by a method of forming an isolation layer according to example embodiments.

Referring to FIG. 16, a first isolation layer is formed by performing a first CMP operation using a first comparative slurry (denoted as “l”) including ceria particles and anionic surfactants at pH 5-6, after performing the second CMP operation and the third CMP operation described with reference to FIGS. 13 through 15.

A second isolation layer is formed by performing a first CMP operation using a second comparative slurry (denoted as “m”) including silica particles at pH 10-11, after performing the second CMP operation and the third CMP operation described with reference to FIGS. 13 through 15.

A third isolation layer is formed by performing a first CMP operation using a first slurry (denoted as “n”) including ceria particles and positive ionic surfactants at pH 5-6, after performing the second CMP operation and the third CMP operation described with reference to FIGS. 13 through 15.

As shown in FIG. 16, if the first comparative slurry (l) is used, then dishing of about 1,400 Å occurs. If the second comparative slurry is used, then dishing of about 1,000 Å occurs. If the first slurry is used, then dishing is decreases by about 200 Å.

As a result, dishing of the silicon oxide layer 104 may be more effectively prevented (or reduced) using a slurry including the positive ionic surfactants having a zeta potential with a polarity opposite to the silicon oxide layer 104 and the abrasives at pH 5-6.

In a method of chemical-mechanical polishing according to example embodiments, a first slurry including ionic surfactants and abrasives with a second polarity opposite to the zeta potential of an insulating layer subjected to polishing is used to perform a first CMP operation, increasing reliability of a semiconductor by preventing (or reducing) dishing of the layer subjected to the polishing. Prior to performing the first CMP operation, a second slurry including ionic surfactants and abrasives with the first polarity may be used to perform a second CMP operation. A third slurry including the abrasives may be used to perform a third CMP operation. In other example embodiments, the first, second and third CMP operation may be combined to planarize the insulating layer subjected to polishing such that productivity of the semiconductor device is increased and/or dishing is prevented (or reduced) to increase reliability.

A method of forming an isolation layer is performed by forming the isolation layer, and planarizing the isolation layer by CMP as described above such that the dishing of the isolation layer is prevented (or reduced) to increase the reliability of the semiconductor device. The second CMP operation having the faster polishing speed and the third CMP operation may be combined, simultaneously increasing the productivity of the semiconductor device.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of chemical-mechanical polishing, comprising:
supplying a first slurry on an insulating layer, wherein the insulating layer has a zeta potential with a first polarity and the first slurry includes a first abrasive and ionic surfactants having a zeta potential with a second polarity opposite to the first polarity; and
performing a first chemical-mechanical polishing operation on the insulating layer using the first slurry.

2. The method of claim 1, further comprising:
supplying a second slurry on the insulating layer, wherein the second slurry includes a second abrasive and a neutral or ionic surfactants having the same polarity as the first polarity; and
performing a second chemical-mechanical polishing operation on the insulating layer using the second slurry, prior to performing the first chemical-mechanical polishing operation.

3. The method of claim 2, further comprising:
supplying a third slurry on the insulating layer, wherein the third slurry includes a third abrasive and excludes surfactants; and
performing a third chemical-mechanical polishing operation on the insulating layer using the third slurry, prior to performing the second chemical-mechanical polishing operation.

4. The method of claim 1, further comprising:
supplying a third slurry on the insulating layer, wherein the third slurry includes a second abrasive and excludes surfactants; and
performing a third chemical-mechanical polishing operation on the insulating layer using the third slurry, prior to performing the first chemical-mechanical polishing operation.

5. The method of claim 1, further comprising:
forming the insulating layer on a mask layer having a zeta potential equal to zero or of the first polarity, prior to performing the first chemical-mechanical polishing operation.

6. The method of claim 1, wherein the first abrasive has a zeta potential of the second polarity.

7. The method of claim 1, further comprising:
forming the insulating layer on a mask layer prior to performing the first chemical-mechanical polishing operation, wherein the insulating layer is formed larger than the mask layer.

8. A method of forming an isolation layer, comprising:
forming a mask layer on a substrate;
etching the substrate to a desired depth using the mask layer such that a trench is formed in the substrate;
forming the insulating layer on the substrate; and
performing the first chemical-mechanical polishing operation according to claim 1, forming the isolation layer.

9. The method of claim 8, further comprising:
supplying a second slurry on the insulating layer, wherein the second slurry includes a second abrasive and a neutral or ionic surfactants having the same polarity as the first polarity; and
performing a second chemical-mechanical polishing operation on the insulating layer using the second slurry, prior to performing the first chemical-mechanical polishing operation.

10. The method of claim 9, further comprising:
supplying a third slurry on the insulating layer, wherein the third slurry includes a third abrasive and excludes surfactants; and
performing a third chemical-mechanical polishing operation on the insulating layer using the third slurry, prior to performing the second chemical-mechanical polishing operation.

11. The method of claim 8, further comprising:
supplying a third slurry on the insulating layer, wherein the third slurry includes a second abrasive and excludes surfactants; and
performing a third chemical-mechanical polishing operation on the insulating layer using the third slurry, prior to performing the first chemical-mechanical polishing operation.

12. The method of claim 8, wherein the mask layer has a zeta potential of zero or the first polarity.

13. The method of claim 8, wherein the first abrasives have a zeta potential of the second polarity.

14. The method of claim 8, wherein the insulating layer is formed larger than the mask layer.

15. The method of claim 8, wherein the insulating layer is a silicon oxide layer, and the mask layer is a silicon nitride layer.

16. The method of claim 15, wherein the first abrasive is formed of ceria particles.

17. The method of claim 15, further comprising:
supplying a second slurry on the insulating layer, wherein the second slurry includes a second abrasive formed of ceria particles and neutral or ionic surfactants having the same polarity as the first polarity; and
performing a second chemical-mechanical polishing operation on the insulating layer using the second slurry, prior to performing the first chemical-mechanical polishing operation.

18. The method of claim 15, further comprising:
supplying a third slurry on the insulating layer, wherein the third slurry includes a second abrasive formed of silica particles and excludes surfactants; and
performing a third chemical-mechanical polishing operation on the insulating layer using the third slurry, prior to performing the first chemical-mechanical polishing operation.

19. The method of claim 15, wherein the first slurry has a pH of 5-6.

20. The method of claim 19, wherein the second polarity is positive, and the first polarity is negative.

21. The method of claim 15, wherein the first slurry has a pH of 10-11.

22. The method of claim 21, wherein the second polarity is positive, and the first polarity is negative.
